(19) United States
(12) Patent Application Publication
(10) Pub. No.: US 2025/0294941 A1
(43) Pub. Date: Sep. 18, 2025

(54) DISPLAY DEVICE AND MANUFACTURING METHOD THEREOF

(71) Applicant: Samsung Display Co., LTD., Yongin-si (KR)

(72) Inventors: Ji-Hwan KIM, Yongin-si (KR); Hiroshi OKUMURA, Yongin-si (KR); Jong Oh SEO, Yongin-si (KR)

(73) Assignee: Samsung Display Co., LTD., Yongin-si (KR)

(21) Appl. No.: 18/968,300

(22) Filed: Dec. 4, 2024

(30) Foreign Application Priority Data
Mar. 13, 2024 (KR) 10-2024-0035312

(51) Int. Cl. H10H 29/24; H10H 20/01; H10H 29/01; H10H 29/30

(52) U.S. Cl. CPC H10H 29/24; H10H 20/016; H10H 29/012; H10H 29/30

(57) ABSTRACT

A display device includes a first barrier layer disposed on a substrate, a lower metal layer disposed on the first barrier layer, and a semiconductor layer disposed on the lower metal layer. In a cross-sectional view, the lower metal layer includes a first part spaced apart from the semiconductor layer and a second part closer to the semiconductor layer, in a plan view, an area of the second part is smaller than an area of the first part, and a side of the semiconductor layer and a side of the second part, which is adjacent to the semiconductor layer, are parallel to each other.

### CROSS-REFERENCE TO RELATED APPLICATION(S)

This application claims priority to and the benefits of Korean Patent Application No. 10-2024-0035312 35 U.S.C. § 119, filed on Mar. 13, 2024, in the Korean Intellectual Property Office the entire contents of which are incorporated herein by reference.

### BACKGROUND

### 1. Technical Field

The disclosure relates to a display device configured to control the excimer laser annealing process and a method of manufacturing the display device by controlling the excimer laser annealing process.

### 2. Description of the Related Art

An excimer laser annealing process is used to convert amorphous silicon of thin-film transistors into low-temperature polysilicon. Low-temperature polysilicon has a more regular silicon composition than amorphous silicon. Therefore, electrons can move more readily in low-temperature polysilicon than in amorphous silicon. In other words, electron mobility is higher in low-temperature polysilicon than in amorphous silicon. Because high electron mobility facilitates the movement of power and data, low-temperature polysilicon is advantageous for implementing high-resolution, slim-bezel, and low-power consumption displays.

### SUMMARY

Embodiments relate to a display device configured to control an excimer laser annealing process and a method of manufacturing the display device by controlling the excimer laser annealing process.

A display device according to an embodiment of the disclosure may include a first barrier layer disposed on a substrate, a lower metal layer disposed on the first barrier layer, and a semiconductor layer disposed on the lower metal layer. In a cross-sectional view, the lower metal layer may include a first part spaced apart from the semiconductor layer and a second part closer to the semiconductor layer, in a plan view, an area of the second part may be smaller than an area of the first part, and a side of the semiconductor layer and a side of the second part, which is adjacent to the semiconductor layer, may be parallel to each other.

The display device may further include a buffer layer disposed between the semiconductor layer and the lower metal layer.

The display device may further include a second barrier layer disposed between the lower metal layer and the buffer layer.

In a cross-sectional view, a thickness of the buffer layer may be about 1 to about 4 times a thickness of the lower metal layer.

In a plan view, the second part may have an additional area.

In a cross-sectional view, the first part and the second part may be continuous.

In a cross-sectional view, the second part may include an inclined surface at an end.

An angle of the inclined surface may be in a range of about 30 degrees to about 60 degrees.

In a cross-sectional view, the first part and the second part may be spaced apart from each other.

The display device may further include a third barrier layer disposed between the first part and the second part.

A method of manufacturing a display device according to an embodiment of the disclosure may include forming a first barrier layer on a substrate, forming a lower metal layer on the first barrier layer, and forming a semiconductor layer on the lower metal layer. The forming of the semiconductor layer on the lower metal layer may include applying the semiconductor layer on the lower metal layer, and irradiating a laser simultaneously to a flat surface and an inclined surface of the semiconductor layer.

An incident angle of the laser may be in a range of about 0 degrees to about 80 degrees. The inclined surface may have a height higher than the flat surface.

In a cross-sectional view, the lower metal layer includes a first part spaced apart from the semiconductor layer and a second part closer to the semiconductor layer, and in a plan view, an area of the second part may be smaller than the area of the first part.

A side of the semiconductor layer and a side of the second part, which is adjacent to the semiconductor layer, may be parallel to each other.

The forming of the lower metal layer may include forming a step in the lower metal layer using a photoresist.

The photoresist may include a step.

The method may further include forming a buffer layer between the semiconductor layer and the lower metal layer.

The method may further include forming a second barrier layer between the lower metal layer and the buffer layer.

In a cross-sectional view, a thickness of the buffer layer may be about 1 to about 4 times a thickness of the lower metal layer.

According to embodiments, an inclined surface may be formed in the semiconductor layer using a stepped lower metal layer.

By performing an excimer laser annealing process using the inclined surface of the semiconductor layer, the regularity of silicon particles may be improved at specific positions of the semiconductor layer.

As a result, electron mobility at a specific location in the semiconductor layer may be improved.

### BRIEF DESCRIPTION OF THE DRAWINGS

FIG. 1 is a schematic diagram illustrating the excimer laser annealing process of a comparative example.

FIG. 2 is a schematic cross-sectional view illustrating that an inclined surface is created in the semiconductor layer by the lower metal layer.

FIG. 3 is a schematic cross-sectional view illustrating an excimer laser annealing process being performed on a semiconductor layer having an inclined surface.

FIG. 4 to FIG. 8 are photographs of the semiconductor layer.

FIG. 9 is an enlarged schematic cross-sectional view illustrating the shape of the lower metal layer.

FIG. 10 is a flowchart of a method of manufacturing a display device including a lower metal layer and a semiconductor layer on a substrate.

FIGS. 11A, 11B, 11C, and 11D are each a schematic cross-sectional view sequentially illustrating a method of manufacturing a stepped lower metal layer according to an embodiment.

FIGS. 12A, 12B, 12C, 12D, and 12E are each a schematic cross-sectional view sequentially illustrating a method of manufacturing a stepped lower metal layer according to another embodiment.

FIG. 13 is a schematic cross-sectional view illustrating a portion of a display device including multiple lower metal layers.

FIG. 14 is a flowchart of a method of manufacturing a display device according to the embodiment of FIG. 13.

FIG. 15 is a schematic diagram of an equivalent circuit of a pixel according to an embodiment.

FIG. 16 is a schematic timing diagram of a signal applied to one pixel according to an embodiment.

FIG. 17 is a plan view illustrating a partial configuration of a display device according to an embodiment.

FIG. 18 is a schematic cross-sectional view taken along line A-A′ of FIG. 17.

FIG. 19 is a plan view of a display device including only a semiconductor layer and a lower metal layer according to an embodiment.

FIG. 20 is an enlarged plan view of a portion of FIG. 19.

FIG. 21 is a schematic cross-sectional view illustrating a method of manufacturing a semiconductor layer after an excimer laser annealing process.

FIG. 22 is a plan view of a display device including only a semiconductor layer and a lower metal layer according to another embodiment.

FIG. 23 is a plan view of a display device including only a semiconductor layer and a lower metal layer according to another embodiment.

FIG. 24 is a plan view of a display device including only a semiconductor layer and a lower metal layer according to another embodiment.

### DETAILED DESCRIPTION OF THE EMBODIMENTS

Hereinafter, with reference to the attached drawings, various embodiments of the disclosure will be described in detail so that those skilled in the art can readily implement it. The disclosure may be implemented in many different forms and is not limited to the embodiments described herein.

In order to clearly explain the disclosure, parts that are not relevant to the description are omitted, and identical or similar components are assigned the same reference numerals throughout the specification.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In addition, throughout the specification, when reference is made to “in a plan view,” this means when the target part is viewed from above, and when reference is made to “in a cross-sectional view,” this means when a cross-section of the target part is cut vertically and viewed from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

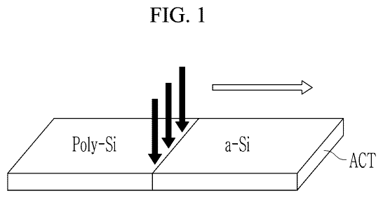

FIG. 1 is a schematic diagram illustrating the excimer laser annealing process of a comparative example.

The excimer laser annealing process may be a laser process used to create low-temperature polysilicon electronic circuit layers. Amorphous silicon may be converted to low-temperature polysilicon using an excimer laser annealing process. Amorphous silicon may be referred to as a-Si, and low-temperature polysilicon may be referred to as Poly-Si. By applying an excimer laser annealing process to a thin-film transistor, the performance of the thin-film transistor may be improved.

The excimer laser annealing process may be performed by irradiating a laser to a semiconductor layer ACT. FIG. 1 schematically illustrates that a laser is irradiated to the semiconductor layer ACT. In FIG. 1, the arrow located at the boundary between amorphous silicon a-Si and low-temperature polysilicon Poly-Si indicates that a laser is irradiated. The arrow progressing from left to right indicates the direction of movement of the laser. The direction of movement of the laser may indicate relative movement between the laser and the semiconductor layer. As the laser progresses to the right, amorphous silicon a-Si may change into low-temperature polysilicon Poly-Si.

Compared to amorphous silicon a-Si, silicon particles of low-temperature polysilicon Poly-Si may have more regular arrangement. Accordingly, electrons may move more readily in low-temperature polysilicon Poly-Si than in amorphous silicon a-Si. This may be referred to as high electron mobility. Because high electron mobility is advantageous to the movement of power and data, low-temperature polysilicon may be advantageous for implementing high-resolution, slim-bezel, and low-power consumption display devices.

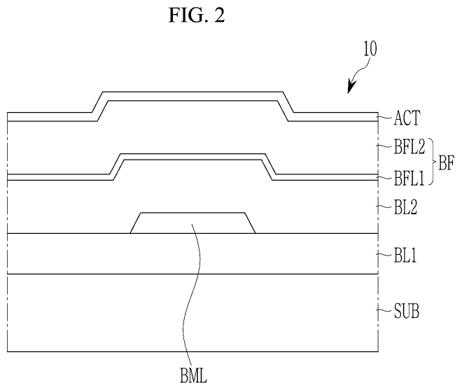

FIG. 2 is a schematic cross-sectional view illustrating that an inclined surface is created in the semiconductor layer by the lower metal layer. FIG. 2 is an enlarged view of a portion of a display device 10 according to an embodiment. In an embodiment, the display device 10 may include a substrate SUB, a first barrier layer BL1, a lower metal layer BML, a second barrier layer BL2, a buffer layer BF, and a semiconductor layer ACT. The buffer layer BF may include a first buffer layer BF1 and a second buffer layer BF2. In an embodiment, the display device 10 may not include some of the substrate SUB, the first barrier layer BL1, the lower metal layer BML, the second barrier layer BL2, the buffer layer BF, and the semiconductor layer ACT and may include other layers.

The first barrier layer BL1 may be disposed on the substrate SUB, and the lower metal layer BML may be disposed on the first barrier layer BL1. The second barrier layer BL2 may be disposed on the first barrier layer BL1 and the lower metal layer BML, the first buffer layer BFL1 may be disposed on the second barrier layer BL2, the first buffer layer BFL1 may be disposed on the first barrier layer BL1 and the lower metal layer BML, and the second buffer layer BFL2 may be disposed on the first buffer layer BFL1. Furthermore, the semiconductor layer ACT may be disposed on the second buffer layer BFL2.

The substrate SUB may be made of a material with rigid properties such as glass. In another embodiment, the substrate SUB may be made of a flexible material such as a plastic or polyimide. In case that the substrate SUB includes a flexible material, the substrate SUB may have a two-layer structure of a barrier layer formed of polyimide and an inorganic insulating material repeatedly formed.

The first barrier layer BL1, the second barrier layer BL2, and the buffer layer BF may be made of an inorganic material and may form an inorganic layer, such as silicon oxide SiOₓ, silicon nitride SiNₓ, silicon oxynitride SiOₓN_{y}, or aluminum oxide AlOₓ and the like, and may also include an organic insulating material such as polyimide and polyacrylic (epoxy added).

The buffer layer BF may block the transfer of impurities from the substrate SUB to the upper layer of the buffer layer BF, especially the semiconductor layer ACT, prevent deterioration of the characteristics of the semiconductor layer ACT, and relieve stress. In case that an excimer laser annealing process is performed on the semiconductor layer ACT, a large amount of heat may be generated, and in case that the heat is transmitted to the lower metal layer BML, peeling of the lower metal layer BML may occur. Therefore, the buffer layer BF disposed between the semiconductor layer ACT and the lower metal layer BML may need to be sufficiently thick. For example, a thickness of the buffer layer BF may be about 1 to about 4 times the thickness of the lower metal layer BML.

The lower metal layer BML may include a metal or such as copper (Cu), molybdenum (Mo), aluminum (Al), titanium (Ti), or an alloy thereof. The lower metal layer BML may additionally include amorphous silicon (a-Si) and may have a single layer or multiple layers. The lower metal layer BML may include a material that blocks light and may prevent light from entering the semiconductor layer ACT.

The semiconductor layer ACT may include multiple doped regions doped with impurities and a channel region between the doped regions. The semiconductor layer ACT may include at least one of polycrystalline silicon and an oxide semiconductor. In case that the semiconductor layer ACT is made of an oxide semiconductor, a separate protective layer may be added to protect the oxide semiconductor material that is vulnerable to environmental factors such as high temperatures.

FIG. 2 schematically illustrates that a step is formed in the semiconductor layer ACT in case that the lower metal layer BML is disposed on the first barrier layer BL1. The formation of a step in the semiconductor layer ACT may mean that a low-height part and a high-height part occur in the semiconductor layer ACT. An inclined surface may be formed between a low-height part and a high-height part of the semiconductor layer ACT. The inclined surface of the semiconductor layer ACT may have an angle. For example, the slope may be greater than 0 degrees and less than 90 degrees, based on the flat surface of the low-height part of the semiconductor layer ACT. Since the lower metal layer BML has a certain thickness or more to block light and is disposed only on a partial area of the first barrier layer BL1, the first barrier layer BL1 and the second barrier layer BL2 disposed on the lower metal layer BML may be stepped. As the second barrier layer BL2 is stepped, the buffer layer BF may be also stepped, and the semiconductor layer ACT may be also stepped. The step may have a shape in which a portion of a layer is convexly raised in a cross-sectional view.

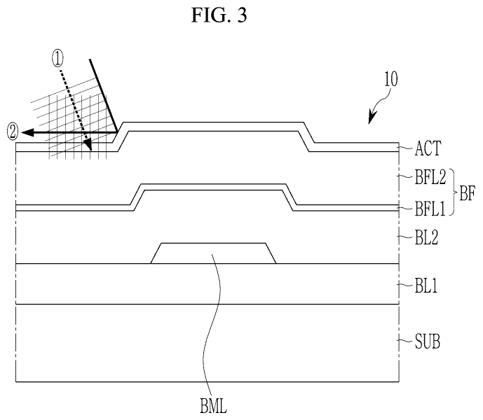

FIG. 3 is a schematic cross-sectional view illustrating an excimer laser annealing process being performed on a semiconductor layer having an inclined surface.

FIG. 3 schematically illustrates an excimer laser annealing process being performed by irradiating a laser to the semiconductor layer ACT on the buffer layer BF. The laser may be simultaneously irradiated to the inclined and flat surfaces of the semiconductor layer ACT. In case that a laser is simultaneously irradiated to an inclined surface and a flat surface, the inclined surface may have a higher height than the flat surface. In other words, the flat surface may be a portion with a lower height than the inclined surface. This is because, as will be described below, the excimer laser annealing process may be performed using interference between incident light from the laser incident on a flat surface and reflected light from the laser reflected from the inclined surface. Amorphous silicon a-Si may be changed into low-temperature polysilicon Poly-Si through the excimer laser annealing process.

The excimer laser annealing process of the comparative example illustrated in FIG. 1 is performed by irradiating a laser to a flat semiconductor layer ACT. In the excimer laser annealing process of the comparative example illustrated in FIG. 1, the laser is irradiated in a direction perpendicular to the flat semiconductor layer ACT. However, the excimer laser annealing process of the embodiment shown in FIG. 3 may use the inclined surface of the semiconductor layer ACT formed by the lower metal layer BML. The laser may be irradiated at an incident angle depending on the angle formed by the inclined surface of the semiconductor layer ACT, and may not be irradiated in a direction perpendicular to the surface of the semiconductor layer ACT. In another embodiment, the laser in the embodiment illustrated in FIG. 3 may be irradiated in a direction perpendicular to the surface of the semiconductor layer ACT. The angle of incidence of the laser in the embodiment of the disclosure is not limited. In an embodiment, the incident angle of the laser may be in a range of about 0 degrees to about 80 degrees.

The laser irradiated to the semiconductor layer ACT to perform the excimer laser annealing process may be divided into incident light (1) in FIG. 3) which is directly irradiated at the location where low-temperature polysilicon Poly-Si is to be formed, and reflected light (2) in FIG. 3) generated by the inclined surface of the semiconductor layer ACT. The location where low-temperature polysilicon Poly-Si is to be formed may be the flat surface of the semiconductor layer ACT. The incident light and reflected light of the laser in FIG. 3 are shown as thick arrows. Incident light is expressed as a dotted line, and reflected light is expressed as a solid line. In FIG. 3, the thin lines expressed in a direction perpendicular to the direction of travel of the incident light and the reflected light represents a same phase in the incident light and the reflected light. For example, a thin line may indicate the position where the phase of the laser is at a peak. The peaks of the incident light and the reflected light may interfere to create constructive interference, which may allow the silicon particles to achieve regularity.

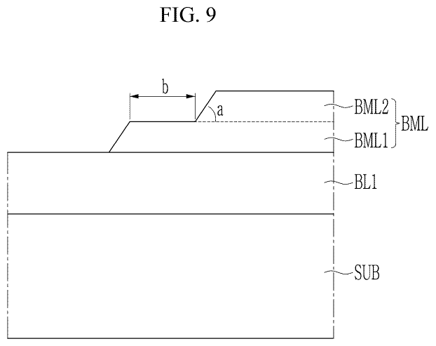

By using the inclined surface created in the semiconductor layer ACT by the lower metal layer BML, low-temperature polysilicon Poly-Si may be formed at a specific location of the semiconductor layer ACT. For example, in a plan view, a second part BML2 (FIG. 9) of the lower metal layer BML may be formed adjacent to the position where low-temperature polysilicon Poly-Si is to be formed. The second part BML2 of the lower metal layer BML may be close to the semiconductor layer ACT in a cross-sectional view, and a step in the lower metal layer BML may be caused by the second part BML2. By performing an excimer laser annealing process using the inclined surface of the semiconductor layer ACT generated by the step of the lower metal layer BML, low-temperature polysilicon Poly-Si may be formed at a specific location of the semiconductor layer ACT. This will be explained in detail below.

Using the step in the semiconductor layer ACT, low-temperature polysilicon Poly-Si formed may have a superior electron mobility compared to low-temperature polysilicon Poly-Si formed on a flat semiconductor layer ACT. This means that in case that low-temperature polysilicon Poly-Si is formed using the step of the semiconductor layer ACT, the silicon particles will have better regularity compared to the low-temperature polysilicon Poly-Si of the comparative example.

Below, it will be explained that low-temperature polysilicon Poly-Si particles formed using steps have better regularity compared to the comparative example.

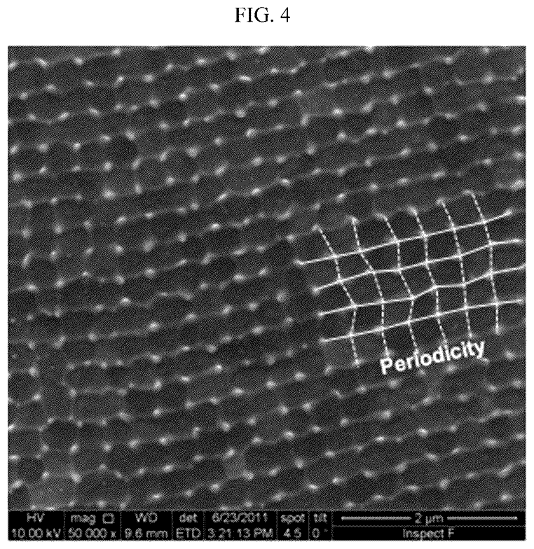

FIG. 4 to FIG. 8 are photographs of the semiconductor layer.

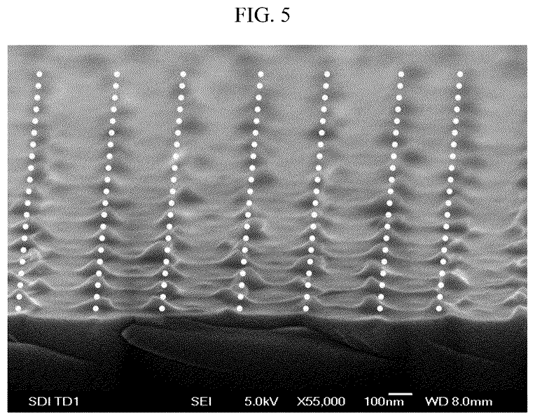

FIG. 4 is a photograph illustrating the silicon of the semiconductor layer ACT having a lattice-like periodicity by the excimer laser annealing process, and FIG. 5 is a photo illustrating the silicon of the semiconductor layer ACT having a linear periodicity by the excimer laser annealing process.

FIGS. 4 and 5 show enlarged views of the semiconductor layer ACT in which amorphous silicon (a-Si) has been converted to low-temperature polysilicon Poly-Si through an excimer laser annealing process. As such, the purpose of the excimer laser annealing process may be to improve electron mobility by ensuring that the silicon particles of the semiconductor layer ACT have regular periodicity. By enhancing the regularity of silicon particles, it may be possible to improve electron mobility.

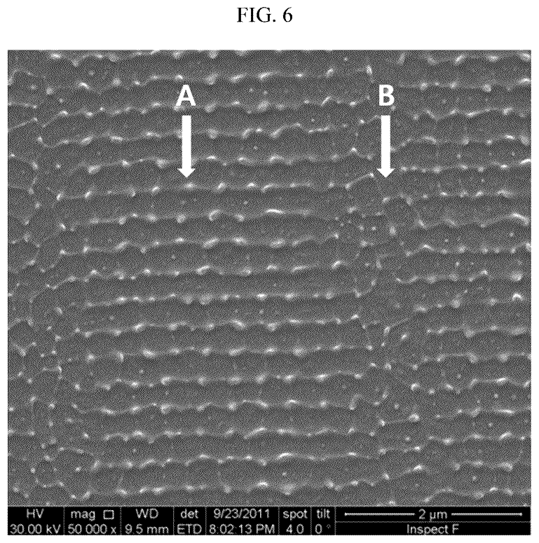

FIG. 6 is a photograph illustrating that the semiconductor layer ACT of the comparative example includes both a periodic part and a non-periodic part.

As in the comparative example of FIG. 1, in case that the excimer laser annealing process is performed by irradiating a laser to the flat surface of the semiconductor layer ACT without using an inclined surface, the silicon particles of the semiconductor layer ACT may have both periodic and non-periodic areas. FIG. 6 is an enlarged photograph of the semiconductor layer ACT of the comparative example. A in FIG. 6 represents a part where silicon particles have periodicity, and B in FIG. 6 represents a part where silicon particles have non-periodicity.

Despite performing excimer laser annealing (ELA) on the semiconductor layer ACT, irregularities may still occur in certain parts of the semiconductor layer ACT. Excimer laser annealing process may induce regularity in silicon particles because the incident light entering the semiconductor layer ACT interferes with the reflected and scattered light from the surface of the semiconductor layer ACT. For example, the case of laser irradiation onto a flat semiconductor layer ACT is explained, as in the comparison example. Although it appears to be a flat semiconductor layer ACT, in an enlarged view, the surface may not be smooth but have a bumpy, uneven shape. Because the surface of the semiconductor layer ACT has an irregular shape, the laser may scatter or reflect. The excimer laser annealing process may use interference between incident light, reflected light, and scattered light to arrange silicon particles regularly. However, the shape of the irregularities on the surface of the semiconductor layer ACT may be irregular and may not be a controllable factor. Therefore, in case that the excimer laser annealing process is performed, the silicon particles may have periodicity at a position of the semiconductor layer ACT, but the silicon particles may have non-periodicity at another positions of the semiconductor layer ACT. Controlling such periodicity and non-periodicity may be difficult when performing an excimer laser annealing process.

In the case of the semiconductor layer ACT having such non-periodicity, the electron mobility of the semiconductor layer ACT may be in a range of about 60 cm2/V·s to about 90 cm2/V·s on average.

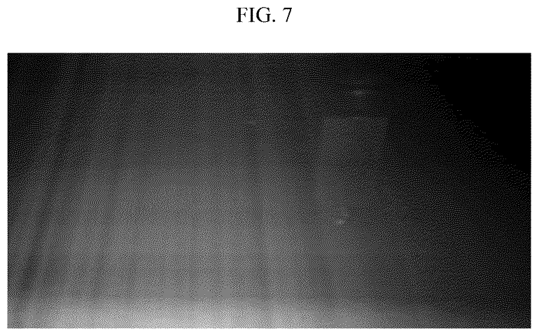

FIG. 7 is a photograph illustrating that the silicon of the semiconductor layer ACT changes its characteristics due to its non-periodicity and appears as streaks.

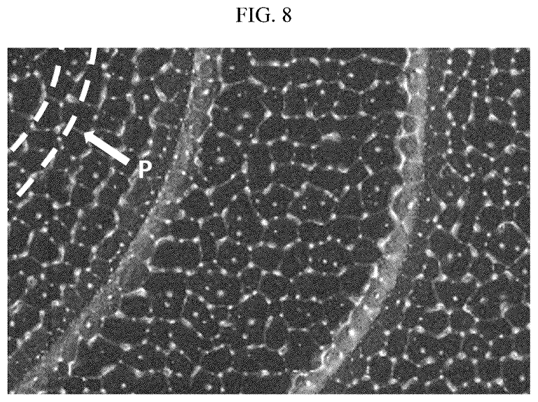

FIG. 8 is a photograph illustrating that the arrangement of silicon crystals has periodicity at a specific position of the semiconductor layer ACT.

When performing an excimer laser annealing process on a flat semiconductor layer ACT as in the comparative example, it may be difficult to control the arrangement of silicon particles to have periodicity at specific positions. This is because the shape of the surface of the semiconductor layer ACT is irregular and cannot be controlled. However, in the embodiment of the disclosure, since the excimer annealing process is controlled using the inclined surface of the semiconductor layer ACT, reflected light that interferes with incident light may be controlled. The reflected light generated using the inclined surface of the semiconductor layer ACT may have greater energy than the reflected light and scattered light generated by the unevenness of the semiconductor layer ACT. Therefore, if an excimer laser annealing process is performed using the step of the semiconductor layer ACT, an array of silicon particles with better regularity may be formed.

P in FIG. 8 is a curved periodic low-temperature polysilicon Poly-Si of silicon particles formed using the inclined surface of the semiconductor layer ACT. In this way, by using the step of the lower metal layer BML, a semiconductor layer ACT with a specific shape and excellent properties may be formed at a specific location.

FIG. 9 is an enlarged schematic cross-sectional view illustrating the shape of the lower metal layer.

The first barrier layer BL1 may be formed on the substrate SUB, and a lower metal layer BML may be formed on the first barrier layer BL1. Although not illustrated in FIG. 9, a buffer layer BF and a barrier layer may be formed on the lower metal layer BML, and a semiconductor layer ACT may be formed on the lower metal layer BML.

The lower metal layer BML in FIG. 9 may have a stepped single-layer structure in a cross-sectional view. The lower metal layer BML may include an inclined surface. The shape of the lower metal layer BML will be described in detail. The step of the lower metal layer BML may mean that the lower metal layer BML is divided into a high-height area and a low-height area in a cross-sectional view. The high-height area may be the upper surface of the second part BML2, and the low-height area may be the exposed upper surface of the first part BML1. An inclined surface may be formed between the high-height area and the low-height area in the lower metal layer BML. The Angle a in FIG. 9 represents the angle of the inclined plane. The angle of the slope is not limited. For example, the angle of the inclined plane may be about 90 degrees. In a cross-sectional view, the lower metal layer BML may be composed of the first part BML1 that is distant from the semiconductor layer ACT and the second part BML2 that is closer to the semiconductor layer ACT. FIG. 9 schematically illustrates a first part BML1 and a second part BML2 in the lower metal layer BML. The first part BML1 may be closer to the substrate SUB, and the second part BML2 may be distant from the substrate SUB. For example, in a cross-sectional view, an area of the lower metal layer BML below a height from the first barrier layer BL1 may be the first part BML1, and an area of the lower metal layer BML above a height from the first barrier layer BL1 may be the second part BML2.

The second part BML2 may be controlled to form a step in the semiconductor layer ACT. By controlling the position of the second part BML2 on the first part BML1, better low-temperature polysilicon Poly-Si may be formed at a specific position of the semiconductor layer ACT.

The first part BML1 may be provided to prevent light from being incident on the semiconductor layer ACT.

Accordingly, in a plan view, the area of the second part BML2 may be smaller than the area of the first part BML1.

In a cross-sectional view, the lower metal layer BML may be stepped, and the second part BML2 may include an inclined surface at an end. As seen in FIG. 9, the end of the second part BML2 may be a part where the second part BML2 no longer extends to the left. In FIG. 9, the right end of the second part BML2 is not illustrated, but the second part BML2 may have a right end. The end of the second part BML2 may mean only one end or both ends. Depending on the angle of the inclined surface at the end of the second part BML2, the angle of the inclined surface of the semiconductor layer ACT may be controlled. In an embodiment, the angle a of the inclined surface of the second part BML2 may be in a range of about 15 degrees to about 75 degrees. For example, the angle α of the inclined surface of the second part BML2 may be in a range of about 30 degrees to about 60 degrees. If the angle of the inclined surface of the second part BML2 is close to 0 degrees, it may be impossible to form a step in the lower metal layer BML, or only a step of a minimal height may be formed. If the angle of the inclined surface of the second part BML2 is close to 90 degrees, it may be difficult to form the reflected light of the laser required in the excimer laser annealing process.

In FIG. 9, flat surface b may be a part of the first part BML1 that does not overlap the second part BML2 in a cross-sectional view. Flat surface b in FIG. 9 may be a portion of the first part BML1 that is not covered by the second part BML2. Flat surface b in FIG. 9 may be a flat surface of the first part BML1 adjacent to an inclined surface of the second part BML2. An excimer laser annealing process using the inclined surface of the semiconductor layer ACT may be performed on the area of the semiconductor layer ACT that overlaps the inclined surface of the second part BML2 and the flat surface b of the adjacent first part BML1. Since the semiconductor layer ACT in the final form may be formed after the excimer laser annealing process is performed on the applied semiconductor layer ACT, the flat surface b of the first part BML1 adjacent to the inclined surface of the second part BML2 may have an appropriate length that is neither too short nor too long.

In a cross-sectional view, the length of the flat surface b of the first part BML1 adjacent to the inclined surface of the second part BML2 may be determined depending on the angle a of the inclined surface of the second part BML2.

The length of the flat surface b of the first part BML1 adjacent to the inclined surface of the second part BML2 may be determined according to the shape of the semiconductor layer ACT.

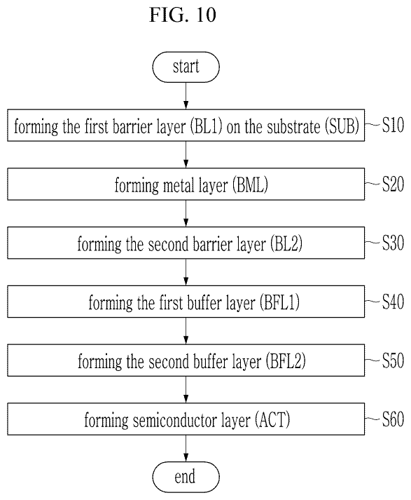

FIG. 10 is a flowchart of a method of manufacturing a display device including a lower metal layer and a semiconductor layer on a substrate.

FIG. 10 illustrates a portion of the process for manufacturing the display device 10. First, a step S10 of forming the first barrier layer BL1 on the substrate SUB may be performed. A step S20 may be performed to form a lower metal layer BML on the first barrier layer BL1, and a step S30 may be performed to form the second barrier layer BL2 on the lower metal layer BML and the first barrier layer BL1. A step S40 of forming a first buffer layer BFL1 on the second barrier layer BL2 may be performed, and a step S50 of forming a second buffer layer BFL2 on the first buffer layer BFL1 may be performed. A step S60 in which the semiconductor layer ACT is formed on the second buffer layer BFL2 may be performed. A step of stacking multiple conductive layers, an insulating layer, and an emitting layer EML may be performed on the semiconductor layer ACT.

Each step may be omitted as needed, and a step of forming a new layer may be performed as needed.

The order of the steps may be changed as needed.

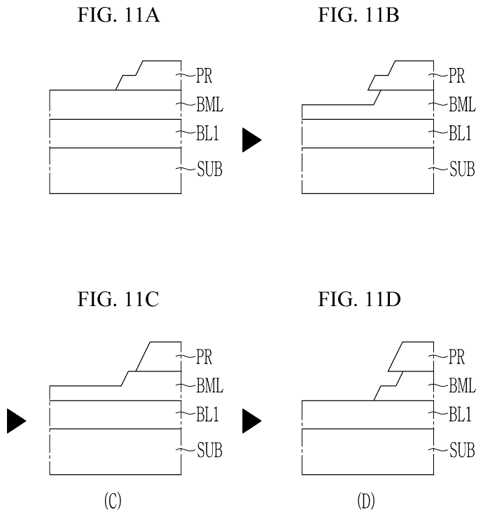

FIGS. 11A to 11D are each a schematic cross-sectional view sequentially illustrating a method of manufacturing a stepped lower metal layer according to an embodiment.

In relation to the step S20 of forming the lower metal layer BML in FIG. 10, the process of forming the stepped lower metal layer BML will be examined in detail.

As shown in FIG. 9, the lower metal layer BML may be composed of a single layer having a first part BML1 and a second part BML2. In a plan view, the second part BML2 may have a smaller area than the first part BML1. Accordingly, in a cross-sectional view, the shape of the lower metal layer BML may be such that the second part BML2 is raised on the first part BML1.

As an embodiment to form a step in the lower metal layer BML, a halftone mask may be applied. The halftone mask may be composed of a part that blocks most of the light, a part that blocks only some of the light, and a part that transmits most of the light.

FIGS. 11A to 11D sequentially illustrate a method of manufacturing a stepped lower metal layer BML using a stepped photoresist PR. The stepped photoresist PR may be manufactured using a technique using a halftone mask. FIGS. 11A to 11D will be described. First, a lower metal layer BML may be applied on the first barrier layer BL1, and a stepped photoresist PR may be placed on the applied lower metal layer BML (FIG. 11A). Afterwards, primary development and etching may be performed (FIG. 11B). Because of this, a part of the lower metal layer BML may be removed. Ashing may be performed on a portion of the stepped photoresist PR (FIG. 11C). As a result, only a part of the photoresist PR may remain, resulting in non-stepped photoresist PR. A lower metal layer stepped BML may be manufactured using the remaining part of the photoresist PR. This may be performed by secondary development and etching (FIG. 11D).

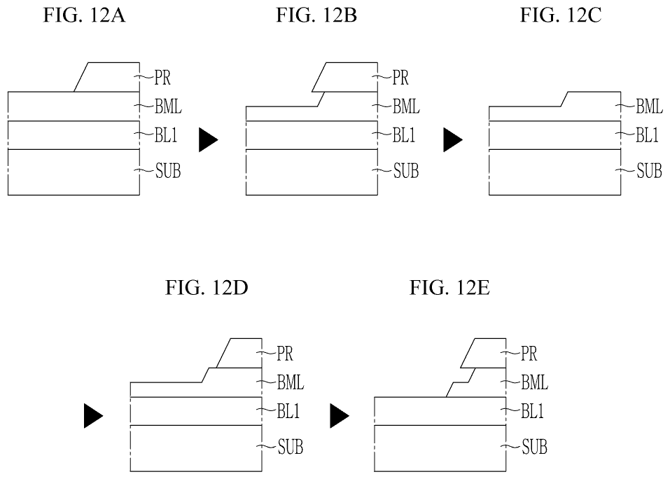

FIGS. 12A to 12E are each a schematic cross-sectional view sequentially illustrating a method of manufacturing a stepped lower metal layer according to another embodiment.

FIGS. 12A to 12E illustrate a method of manufacturing a stepped lower metal layer BML without using a stepped photoresist PR. A stepped bottom metal layer BML may be manufactured by repeatedly using a non-stepped photoresist PR. FIGS. 12A to 12E will be described. First, the lower metal layer BML may be applied on the first barrier layer BL1, and the photoresist PR may be placed on the applied lower metal layer BML (FIG. 12A). Afterwards, primary development and etching may be performed (FIG. 12B). Because of this, a part of the lower metal layer BML may be removed. The entire photoresist PR formed on the lower metal layer BML may be removed by ashing (FIG. 12C). A new non-stepped photoresist PR may be formed on the lower metal layer BML (FIG. 12D), and secondary development and etching may be performed (FIG. 12E).

Using a stepped photoresist PR to manufacture a stepped lower metal layer BML may have an advantage that the step of removing the existing photoresist PR and forming a new photoresist PR on the lower metal layer BML may be omitted.

In case that the lower metal layer BML is manufactured using a non-stepped photoresist PR, there may be an advantage in that a stepped separate photoresist PR is not needed.

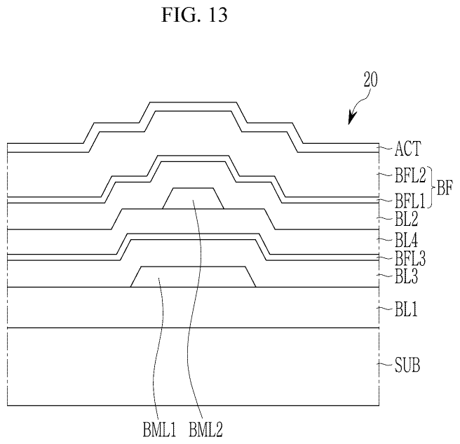

FIG. 13 is a schematic cross-sectional view illustrating a portion of a display device including multiple lower metal layers.

FIG. 13 schematically illustrates another embodiment of the lower metal layer BML for forming the semiconductor layer ACT having an inclined surface. For example, an inclined surface may be formed in the semiconductor layer ACT by using multiple lower metal layers BML. The lower metal layers BML may form multiple layers and may include a first part BML1 and a second part BML2, respectively. In a cross-sectional view, the first part BML1 and the second part BML2 may be separated from each other. For example, the first part BML1 may be a lower metal layer distant from the semiconductor layer ACT, and the second part BML2 may be a lower metal layer closer to the semiconductor layer ACT. Also, in a cross-sectional view, the lower metal layer BML that is below a certain height from the first barrier layer BL1 may be the first part BML1, and the lower metal layer BML that is more than a certain height from the first barrier layer BL1 may be the second part BML2.

The display device 20 in FIG. 13 will be described. The first barrier layer BL1 may be disposed on the substrate SUB, and the first part BML1 may be disposed on the first barrier layer BL1. The first part BML1 disposed on the first barrier layer BL1 may be the lower metal layer BML distant from the semiconductor layer ACT. A third barrier layer BL3 may be disposed on the first barrier layer BL1 and the first part BML1, and the third buffer layer BF may be disposed on the third barrier layer BL3. A fourth barrier layer BL4 may be disposed on the third buffer layer BF. The second part BML2 may be disposed on the fourth barrier layer BL4. The second part BML2 disposed on the fourth barrier layer BL4 may be a lower metal layer BML closer to the semiconductor layer ACT. The second barrier layer BL2 may be disposed on the fourth barrier layer BL4 and the second part BML2. The first buffer layer BFL1 may be disposed on the second barrier layer BL2, and the second buffer layer BFL2 may be disposed on the first buffer layer BFL1. The first buffer layer BFL1 and the second buffer layer BFL2 may form a buffer layer BF. The semiconductor layer ACT may be disposed on the buffer layer BF, and the stepped semiconductor layer ACT caused by the second part BML2.

In this way, by using multiple lower metal layers BML, the inclined surface position of the semiconductor layer ACT may be controlled by disposing the second part BML2 at a specific position. Because of this, it may be possible to manufacture a semiconductor layer ACT having an inclined surface at a specific position without manufacturing a stepped single-layer lower metal layer BML.

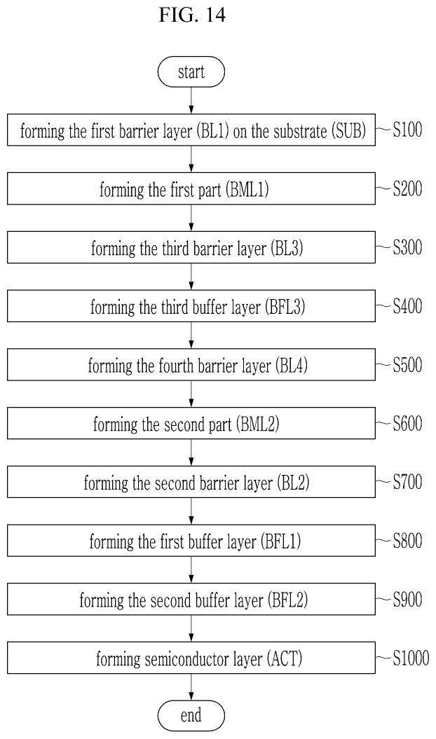

FIG. 14 is a flowchart of a method of manufacturing a display device according to the embodiment of FIG. 13. First, a step S100 of forming the first barrier layer BL1 on the substrate SUB may be performed. Subsequently, a step S200 of forming the first part BML1 on the first barrier layer BL1 may be performed, and a step S300 of forming the third barrier layer BL3 on the first barrier layer BL1 and the first part BML1 may be performed. Afterwards, a step S400 may be performed to form a third buffer layer BF on top of the third barrier layer BL3, and a step S500 may be performed to form a fourth barrier layer BL4 on top of the third buffer layer BF. Subsequently, a step S600 of forming the second part BML2 on the fourth barrier layer BL4 may be performed, and a step S700 of forming the second barrier layer BL2 on the fourth barrier layer BL4 and the second part BML2 may be performed. A step S800 of forming a first buffer layer BFL1 may be performed on the second barrier layer BL2, and a step S900 of forming a second buffer layer BFL2 may be performed on the first buffer layer BFL1. The first buffer layer BFL1 and the second buffer layer BFL2 may form a buffer layer BF. Subsequently, a step S1000 of forming a semiconductor layer ACT on the second buffer layer BFL2 may be performed. The stepped semiconductor layer ACT may include inclined surfaces. Multiple conductive layers, insulating layers, and light emitting layers EML may be stacked on the semiconductor layer ACT.

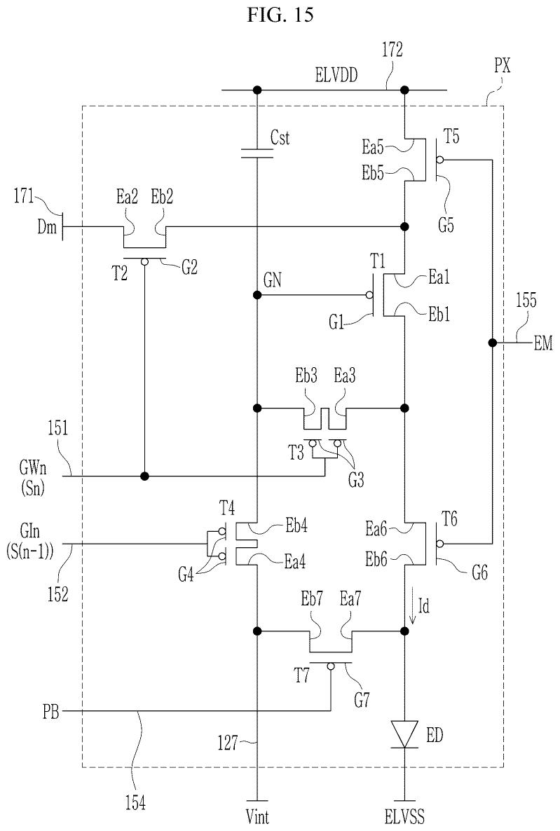

FIG. 15 is a schematic diagram of an equivalent circuit of a pixel according to an embodiment.

Referring to FIG. 15, a display device according to an embodiment may include multiple pixels PX and multiple signal lines 127, 151, 152, 154, 155, 171, 172 capable of displaying an image. A pixel PX may include multiple transistors T1, T2, T3, T4, T5, T6, T7 and a capacitor Cst connected to multiple signal lines 127, 151, 152, 154, 155, 171, 172, and may include at least one light emitting diode ED. The description will be based on an embodiment in which a pixel PX includes one light emitting diode ED.

The signal lines 127, 151, 152, 154, 155, 171, 172 may include an initialization voltage line 127, multiple scan lines 151, 152, 154, a light emitting control line 155, a data line 171, and a drive voltage line 172.

The initialization voltage line 127 may transmit an initialization voltage Vint. The scan lines 151, 152, 154 may respectively transmit scan signals GWn, GIn, PB. The scan signals GWn, GIn, PB may transmit gate-on voltage and gate-off voltage that can turn on/off the transistors T2, T3, T4, T7 included in the pixel PX.

The scan lines 151, 152, 154 connected to one pixel PX may include a first scan line 151, which can transmit the scan signal GWn, a second scan line 152 capable of transmitting a scan signal Gin having a different gate-on timing than the first scan line 151, and a third scan line 154 which can transmit a bypass signal PB. An embodiment in which the second scan line 152 transmits the gate-on voltage at a timing earlier than the timing of the first scan line 151 will be described. For example, if the scan signal GWn is an (n)th scan signal Sn (n is a natural number of 1 or more) among the scan signals applied during one frame, the scan signal GIn may be the (n−1)th scan signal, which is a front-end scan signal such as S(n−1), and the bypass signal PB may be the (n)th scan signal Sn. However, the disclosure is not limited to thereto, and the bypass signal PB may be a scan signal different from the (n)th scan signal Sn.

The light emission control line 155 may transmit a control signal, for example, the light emission control signal EM may control the light emission of the light emitting diode ED included in the pixel PX. The control signal transmitted by the light emission control line 155 may transmit a gate-on voltage and a gate-off voltage, and may have a different waveform from the scan signal transmitted by the scan lines 151, 152, 154.

A data line 171 may transmit a data signal Dm, and the driving voltage line 172 may transmit a driving voltage ELVDD. A data signal Dm may have a different voltage level depending on the image signal input to the display device, and the driving voltage ELVDD may have a substantially constant level.

Although not shown, the display device may further include a driver that transmits signals to the signal lines 127, 151, 152, 154, 155, 171, 172.

The transistors T1, T2, T3, T4, T5, T6, T7 included in a pixel PX may include a driving transistor T1, a second transistor T2, a third transistor T3, a fourth transistor T4, a fifth transistor T5, a sixth transistor T6, and a seventh transistor T7.

The first scan line 151 may deliver a scan signal GWn to the second transistor T2 and the third transistor T3, the second scan line 152 may deliver a scan signal GIn to the fourth transistor T4, the third scan line 154 may deliver a bypass signal PB to the seventh transistor T7, and the light emission control line 155 may deliver a light emission control signal EM to the fifth transistor T5 and the sixth transistor T6.

The gate electrode G1 of the driving transistor T1 may be connected to an end of the capacitor Cst through the driving gate node GN, a first electrode Ea1 of the driving transistor T1 may be connected to the driving voltage line 172 via the fifth transistor T5, and a second electrode Eb1 of the driving transistor T1 may be connected to the anode of the light emitting diode ED via the sixth transistor T6. The driving transistor T1 may receive the data signal Dm transmitted by the data line 171 according to the switching operation of the second transistor T2 and supply the driving current Id to the light emitting diode ED.

The gate electrode G2 of the second transistor T2 may be connected to the first scan line 151, the first electrode Ea2 of the second transistor T2 may be connected to the data line 171, and the second electrode Eb2 of the second transistor T2 may be connected to the first electrode Ea1 of the driving transistor T1 and may be connected to the driving voltage line 172 via the fifth transistor T5. The second transistor T2 may be turned on according to the scan signal GWn received through the first scan line 151, and may deliver the data signal Dm transmitted from the data line 171 to the first electrode Ea1 of the drive transistor T1.

The gate electrode G3 of the third transistor T3 may be connected to the first scan line 151, and the first electrode Ea3 of the third transistor T3 may be connected to the second electrode Eb1 of the driving transistor T1 and may be connected to the anode of the light emitting diode ED via the sixth transistor T6. The second electrode Eb3 of the third transistor T3 may be connected to the second electrode Eb4 of the fourth transistor T4, an end of the capacitor Cst, and the gate electrode G1 of the driving transistor T1. The third transistor T3 may be turned on according to the scan signal GWn received through the first scan line 151 to connect the gate electrode G1 and the second electrode Eb1 of the driving transistor T1 to each other, and thereby the transistor T1 may be diode-connected.

The gate electrode G4 of the fourth transistor T4 may be connected to the second scan line 152, the first electrode Ea4 of the fourth transistor T4 may be connected to the initialization voltage Vint terminal, and the second electrode Eb4 of the transistor T4 may connected to an end of the capacitor Cst and the gate electrode G1 of the driving transistor T1 via the second electrode Eb3 of the third transistor T3. The fourth transistor T4 may be turned on according to the scan signal GIn received through the second scan line 152, and perform an initialization operation that delivers the initialization voltage Vint to the gate electrode G1 of the driving transistor T1 and reset the voltage of the gate electrode G1 of the driving transistor T1.

The gate electrode G5 of the fifth transistor T5 may be connected to the emission control line 155, the first electrode Ea5 of the fifth transistor T5 may be connected to the driving voltage line 172, and the second electrode Eb5 of the fifth transistor T5 may be connected to the first electrode Ea1 of the driving transistor T1 and the second electrode Eb2 of the second transistor T2.

The gate electrode G6 of the sixth transistor T6 may be connected to the light emission control line 155, the first electrode Ea6 of the sixth transistor T6 may be connected to the second electrode Eb1 of the driving transistor T1 and the first electrode Ea3 of the third transistor T3, and the second electrode Eb6 of the sixth transistor T6 may be electrically connected to the anode of the light emitting diode ED. The fifth transistor T5 and the sixth transistor T6 may be simultaneously turned on according to the light emission control signal EM received through the light emission control line 155, which allows the driving voltage ELVDD to be compensated and transmitted to the light emitting diode ED via the driving connector T1.

The gate electrode G7 of the seventh transistor T7 may be connected to the third scan line 154, the first electrode Ea7 of the seventh transistor T7 may be connected to the second electrode Eb6 of the sixth transistor T6 and the anode of the light emitting diode ED, and the second electrode Eb7 of the seventh transistor T7 may be connected to the initialization voltage Vint terminal and the first electrode Ea4 of the fourth transistor T4

The transistors T1, T2, T3, T4, T5, T6, T7 may be P-type channel transistors such as PMOS, but are not limited thereto, and among the transistors T1, T2, T3, T4, T5, T6, T7, at least one may be an N-type channel transistor, or may include a P-type channel transistor and an N-type channel transistor.

As described above, an end of the capacitor Cst may be connected to the gate electrode G1 of the driving transistor T1, and another end may be connected to the driving voltage line 172. The cathode of the light emitting diode ED may be connected to a common voltage ELVSS terminal that transmits the common voltage ELVSS and may receive the common voltage ELVSS.

Although a structure in which one pixel includes 7 transistors and 1 capacitor has been described above, the disclosure is not limited thereto, and the number of transistors and capacitors and the connection relationship between the transistors and capacitors may be varied in one pixel PX of the display device.

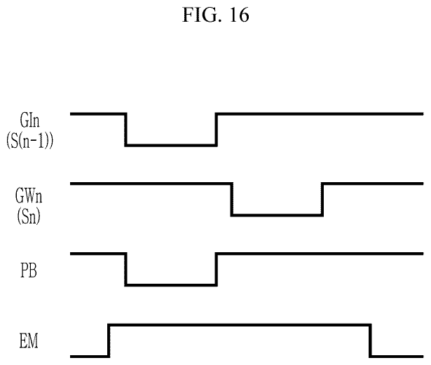

FIG. 16 is a schematic timing diagram of a signal applied to one pixel according to an embodiment.

During the initialization period, the low-level front-end scan signal Sn−1 may be supplied to the pixel PX through the second scan line 152. The second scan line 152 may be a front-end scan line. The fourth transistor T4 may be turned on by the scan signal Sn−1, and the initialization voltage Vint may be applied to the gate electrode G1 of the drive transistor T1 and the second storage electrode E2 of the capacitor Cst through the fourth transistor T4. As a result, the driving transistor T1 and the capacitor Cst may be initialized. Since the voltage of the initialization voltage Vint is low, the driving transistor T1 may be turned on.

During the initialization period, a low-level bypass signal PB may be also applied to the seventh transistor T7. The seventh transistor T7 may be turned on, causing the initialization voltage Vint to be applied to the anode of the light emitting diode ED through the seventh transistor T7. As a result, the anode of the light emitting diode ED may be also initialized.

Thereafter, the low-level scan signal Sn may be supplied to the pixel PX through the scan line 151 during the data entry period. The second transistor T2 and the third transistor T3 may be turned on by the low-level scan signal Sn.

In case that the second transistor T2 is turned on, the data voltage Dm may pass through the second transistor T2 and may be input to the first electrode Ea1 of the driving transistor T1.

During the data entry period, the third transistor T3 may be turned on, and as a result, the second electrode Eb1 of the driving transistor T1 may be electrically connected to the gate electrode G1 and the second holding electrode E2 of the capacitor Cst. The gate electrode G1 of the driving transistor T1 and the second electrode Eb1 may be connected to form a diode. The driving transistor T1 may be turned on because a low voltage (initialization voltage Vint) is applied to the gate electrode G1 during the initialization period. As a result, the data voltage Dm input to the first electrode Ea1 of the driving transistor T1 may pass through the channel of the driving transistor T1, may be output from the second electrode Eb1, may pass through the third transistor T3, and may be stored in the second storage electrode E2 of the capacitor Cst.

The voltage applied to the second storage electrode E2 may change depending on the threshold voltage Vth of the driving transistor T1, and in case that the data voltage Dm is applied to the first electrode Ea1 of the driving transistor T1 and the initialization voltage Vint is applied to the gate electrode G1 of the driving transistor T1, the voltage output to the second electrode Eb1 may have Vgs+Vth. Here, Vgs may be the difference between the voltage applied to the gate electrode G1 and the first electrode Ea1 of the driving transistor T1, and may have a value of Dm-Vint. Therefore, the voltage output from the second electrode Eb1 and stored in the second storage electrode E2 may have a value of Dm−Vint+Vth.

Thereafter, during the light emission period, the light emission control signal EM supplied from the light emission control line 155 may have a low-level value, and the fifth transistor T5 and the sixth transistor T6 may be turned on. As a result, the driving voltage ELVDD may be applied to the first electrode Ea1 of the driving transistor T1, and the second electrode Eb1 of the driving transistor T1 may be connected to the light emitting diode ED. The driving transistor T1 may generate a driving current Id according to the voltage difference between the voltage of the gate electrode G1 and the voltage of the first electrode Ea1 (for example, the driving voltage ELVDD). The driving current Id of the driving transistor T1 may have a value proportional to the square of Vgs-Vth. Here, the value of Vgs may be equal to the voltage difference across the capacitor Cst, and the value of Vgs may be the value of Vg-Vs, which is Dm-Vint Vth-ELVDD. The value of Vgs-Vth may be the value of Dm-Vint
ELVDD by subtracting Vth. For example, the driving current Id of the driving transistor T1 may have an output current that is unrelated to the threshold voltage Vth of the driving transistor T1.

Therefore, even if the driving transistor T1 located in each pixel PX has a different threshold voltage Vth due to process distribution, the output current of the driving transistor T1 may be kept constant, improving the non-uniformity of characteristics.

In the above calculation formula, the Vth value may have a value slightly greater than 0 or a negative value in the case of a P-type transistor using a polycrystalline semiconductor. The expressions of + and − may change depending on the direction in which the voltage is calculated. However, there is no change in the fact that the driving current Id, which is the output current of the driving transistor T1, may be made to have a value independent of the threshold voltage Vth.

In case that the above-mentioned light emission section ends, an initialization period may start again and a same operation may be repeated from the beginning.

In the above, the third transistor T3 may be a switching transistor. Hereinafter, the planar and cross-sectional shapes of the display device according to an embodiment will be further described, focusing on the driving transistor T1, the third transistor T3, and the capacitor Cst.

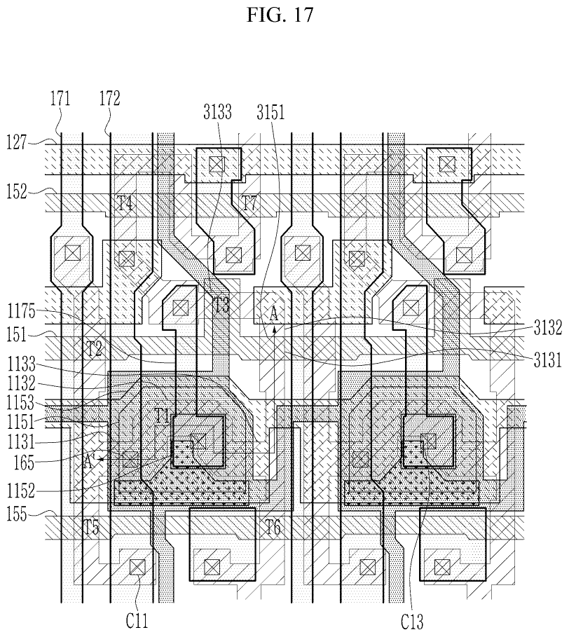

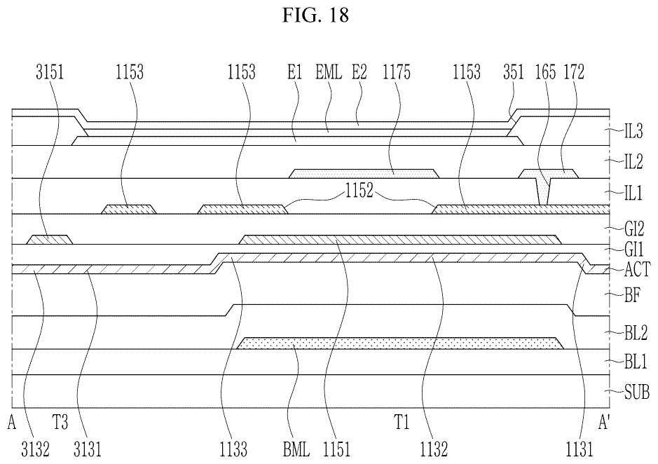

FIG. 17 is a plan view illustrating a partial configuration of a display device according to an embodiment. FIG. 18 is a schematic cross-sectional view taken along line A-A′ of FIG. 17. FIG. 17 is a plan view showing only the lower metal layer BML, the semiconductor layer ACT, the first gate conductive layer, the second gate conductive layer, and the data conductive layer among the components of the display device. Other components that make up the display device are omitted. In a cross-sectional view, the lower metal layer BML was expressed as the first part BML1 distant from the semiconductor layer ACT and the second part BML2 close to the semiconductor layer ACT.

FIG. 18 is a schematic cross-sectional view taken along line A-A′ of FIG. 17 and schematically illustrates a cross-sectional view of a display device, including a lower metal layer BML, a semiconductor layer ACT, a first gate conductive layer, a second gate conductive layer, and a data conductive layer, as well as other components. Other components include the substrate SUB, the first barrier layer BL1, the second barrier layer BL2, the buffer layer BF, a first gate insulating layer GI1, a second gate insulating layer GI2, a first insulating layer IL1, a second insulating layer IL2, a barrier rib IL3, a first electrode E1, a second electrode E2, and the light emitting layer EML. Accordingly, the vertical stacking relationship between the components of the display device may be identified.

With reference to FIGS. 17 and 18, each layer will be looked at in more detail.

The substrate SUB may be made of a material with rigid characteristics or a material with flexibility. In the case of a flexible substrate SUB, the substrate SUB may have a two-layer structure of polyimide and a barrier layer formed of an inorganic insulating material on the polyimide.

The first barrier layer BL1 may be disposed on the substrate SUB. The first barrier layer BL1 may include an inorganic material and may form an inorganic layer. In another embodiment, the first barrier layer BL1 may include an organic insulating material.

The lower metal layer BML may be disposed on the first barrier layer BL1. The lower metal layer BML may include a material that blocks light and may be disposed on a portion of the first barrier layer to prevent light from entering the semiconductor layer ACT. The lower metal layer BML may include a metal such as copper (Cu), molybdenum (Mo), aluminum (Al), titanium (Ti), or an alloy thereof. The lower metal layer BML may have a single layer. The lower metal layer BML may include the first part BML1 and the second part BML2.

The second barrier layer BL2 may be disposed on a portion of the lower metal layer BML and the first barrier layer BL1. The buffer layer BF may be disposed on the second barrier layer BL2. The second barrier layer BL2 and the buffer layer BF may include an inorganic material and may form an inorganic layer. In another embodiment, the second barrier layer BL2 and the buffer layer BF may include an organic insulating material. The second barrier layer BL2 and the buffer layer BF may have a step equal to the thickness of the lower metal layer BML.

A channel 1132, a first region 1131 and a second region 1133 of the driving transistor T1, and a channel 3132, a first region 3131, and a second region 3133 of third transistor T3 may be disposed on the buffer layer BF. The semiconductor layer ACT may include not only the driving transistor T1 and the third transistor T3, as well as channel, a first region, and a second region of each of the second transistor T2, the fourth transistor T4, the fifth transistor T5, the sixth transistor T6, and the seventh transistor T7.

The channel 1132, the first region 1131, and second region 1133 of the driving transistor T1, the channel 3132, the first region 3131, and the second region 3133 of the third transistor T3 may be connected to each other and formed as a whole. The second region 1133 of the driving transistor T1 may extend from the first region 3131 of the third transistor T3.

In order to prevent light from being incident on the driving transistor T1, the lower metal layer BML may overlap the channel 1132, the first region 1131, and the second region 1133 of the driving transistor T1 in a plan view. For example, the first part BML1 of the lower metal layer BML may overlap the channel 1132, the first region 1131, and the second region 1133 of the driving transistor T1.

The second part BML2 of the lower metal layer BML may be disposed on a part of the first part BML1 of the lower metal layer BML in order to perform an excimer laser annealing process using an inclined surface. The area of the semiconductor layer ACT that overlaps the second part BML2 may rise convexly upward as much as the thickness of the second part BML2.

The channel 1132 of the driving transistor T1 may have a curved shape in a plan view. However, the shape of the channel 1132 of the driving transistor T1 is not limited to this and may change in various ways. For example, the channel 1132 of the driving transistor T1 may be bent into a different shape or may be shaped like a bar. The first region 1131 and the second region 1133 of the driving transistor T1 may be disposed on sides of the channel 1132 of the driving transistor T1.

The second region 1133 of the driving transistor T1 may extend up and down in a plan view, so that the downwardly extending portion may be connected to the first region of the sixth transistor T6, and the upwardly extending portion may be connected to the first region 3131 of the third transistor T3.

The first region 3131 and the second region 3133 of the third transistor T3 may be disposed on sides of the channel 3132 of the third transistor T3. An end of the third transistor T3 may be connected to the second region 1133 of the driving transistor T1, and another end may be connected to the second region of the fourth transistor T4.

A first gate insulating layer GI1 may be disposed on the substrate SUB and the semiconductor layer ACT. At least a portion of the first gate insulating layer GI1 may be disposed directly above the buffer layer BF. For example, at least a portion of the first gate insulating layer GI1 may be in contact with the buffer layer BF.

A first gate conductive layer may be disposed on the first gate insulating layer GI1. The first gate conductive layer may include a first scan line 151, a second scan line 152, and an emission control line 155. The first scan line 151, the second scan line 152, and the emission control line 155 may extend approximately in a row direction. Each of the first scan line 151, the second scan line 152, and the emission control line 155 may be connected to multiple pixels. For example, multiple pixels disposed in a same row may be connected to a same first scan line 151, second scan line 152, and emission control line 155. The first scan line 151 may be connected to the gate electrode of the second transistor T2 and the gate electrode 3151 of the third transistor T3. The first scan line 151 may be integrated with the gate electrode of the second transistor T2 and the gate electrode of the third transistor T3. The second scan line 152 may be connected to the gate electrode of the fourth transistor T4. The second scan line 152 may be integrated with the gate electrode of the fourth transistor T4. The second scan line 152 may be connected to the gate electrode of the seventh transistor T7 located in the pixel of the previous stage. For example, the third scan line 154 connected to the seventh transistor T7 may be formed of the second scan line 152 at the rear end. The emission control line 155 may be connected to the gate electrode of the fifth transistor T5 and the gate electrode of the sixth transistor T6. The emission control line 155 may be integrated with the gate electrode of the fifth transistor T5 and the gate electrode of the sixth transistor T6.

The first gate conductive layer may further include the gate electrode 1151 of the driving transistor T1. As shown in FIG. 18, the gate electrode 1151 of the driving transistor T1 may overlap the channel 1132 of the driving transistor T1 in a plan view.

As illustrated in FIG. 18, the second gate insulating layer GI2 may be disposed on the first gate conductive layer and the first gate insulating layer GI1. At least a portion of the second gate insulating layer GI2 may be disposed directly above the first gate insulating layer GI1.

A second gate conductive layer may be disposed on the second gate insulating layer GI2. The second gate conductive layer may include a storage electrode 1153. The storage electrode 1153 may overlap the first gate electrode 1151 in a plan view to form a capacitor Cst. As illustrated in FIG. 18, an opening 1152 may be formed in the storage electrode 1153 of the capacitor Cst. The opening 1152 of the storage electrode 1153 of the capacitor Cst may overlap the gate electrode 1151 of the driving transistor T1 in a plan view. The first connection electrode 1175 may overlap the gate electrode 1151 of the driving transistor T1 in a plan view. Although not illustrated in FIG. 18, the first connection electrode 1175 may be connected to the gate electrode 1151 of the driving transistor T1 through the opening 1152.

The second gate conductive layer may further include an initialization voltage line 127. The initialization voltage line 127 may extend approximately in the row direction. The initialization voltage line 127 may be connected to multiple pixels. For example, multiple pixels disposed in a same row may be connected to a same initialization voltage line 127.

The first insulating layer IL1 may be disposed on the second gate conductive layer and the second gate insulating layer GI2. A data conductive layer including a data line 171, a driving voltage line 172, and the connection electrode 1175 may be disposed on the first insulating layer IL1. The data conductive layer may include the data line 171, the driving voltage line 172, and the connection electrode 1175.

The data line 171 and the driving voltage line 172 may extend approximately in the column direction. The data line 171 may be connected to the second transistor T2. The driving voltage line 172 may be connected to the fifth transistor T5. As illustrated in FIG. 18, the driving voltage line 172 may be connected to the storage electrode 1153 through the contact hole 165. The driving voltage ELVDD may be transmitted to the storage electrode 1153.

The connection electrode 1175 may be connected to the gate electrode 1151 of the first driving transistor through the opening 1152 of the storage electrode 1153. The connection electrode 1175 may be connected to the third transistor T3 and the fourth transistor T4. The connection electrode 1175 may be connected to the second region of the third transistor T3 and the second region of the fourth transistor T4.

The data conductive layer may additionally include other connection electrodes. The first region of the fourth transistor T4 and the second region of the seventh transistor T7 may be connected to the initialization voltage line 127 by this connection electrode. There may be a connection electrode that overlaps the sixth transistor T6 and may be connected to the second region of the sixth transistor T6.

As illustrated in FIG. 18, the driving voltage line 172 may be connected to the storage electrode 1153 through the contact hole 165.

The driving voltage line 172 may be connected to the fifth transistor T5 through the contact hole C11. An end of the connection electrode 1175 may be connected to the gate electrode 1151 of the first driving transistor through the contact hole C13.

Above the data conductive layer and the first insulating layer IL1, the second insulating layer IL2, the first electrode E1, the barrier rib IL3, the emitting layer EML, and the second electrode E2 may be sequentially located as mentioned earlier.

The buffer layer BF may be disposed between the substrate SUB and the semiconductor layer ACT.

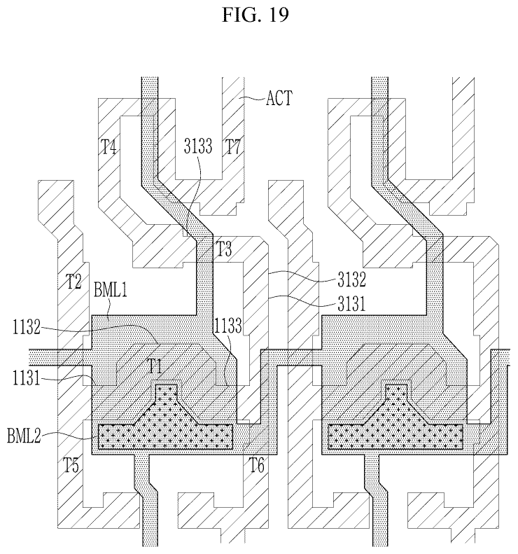

FIG. 19 is a plan view of a display device including only a semiconductor layer and a lower metal layer according to an embodiment.

The lower metal layer BML may include the first part BML1 and the second part BML2. The second part BML2 may be disposed between the semiconductor layer ACT and the first part BML1. The first part BML1 may prevent light from entering the semiconductor layer ACT. Accordingly, the first part BML1 may be arranged to overlap the area of the driving transistor T1 in a plan view. The first part BML1 may be arranged to overlap a part of the area of the driving transistor T1 in a plan view. The second part BML2 may be a part for forming a step in the semiconductor layer ACT. Accordingly, a side of the semiconductor layer ACT and a side of the second part BML2, which is adjacent to the semiconductor layer, may be parallel to each other. Here, a side of the semiconductor layer ACT and a side of the second part BML2 that are parallel to each other may be referred to as sides corresponding to each other, and the side of the semiconductor layer ACT and the side of the second part BML2 corresponding to each other may be parallel to each other in a plan view. This may mean that among the sides forming the semiconductor layer ACT and the sides forming the second part BML2 in a plan view, the sides that are close to each other may extend in a same direction while maintaining a certain distance. A side of the adjacent semiconductor layer ACT and a side of the second part BML2 may include straight lines and curves. If the side of the semiconductor layer ACT and the side of the second part BML2 are curved, the space (horizontal space) between the two corresponding curves may be constant. In another embodiment, the side of the adjacent semiconductor layer ACT and the side of the second part BML2 may be formed only of straight lines or curves.

The semiconductor layer ACT may further include the driving transistor T1 and the third transistor T3, as well as a channel, a first region, and a second region of each of the second transistor T2, the fourth transistor T4, the fifth transistor T5, the sixth transistor T6, and the seventh transistor T7.

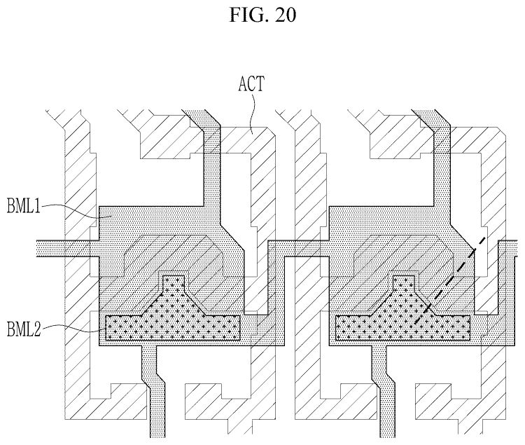

FIG. 20 is an enlarged plan view of a part of FIG. 19.

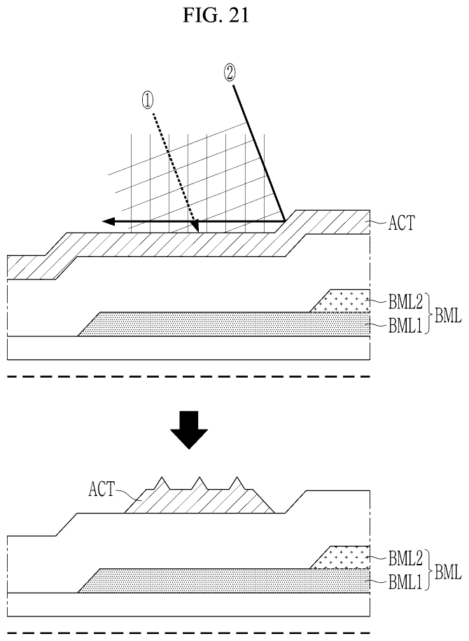

FIG. 20 schematically illustrates an embodiment illustrating the arrangement of the semiconductor layer ACT and the first part BML1 and the second part BML2 of the drive transistor T1 part, by enlarging the drive transistor T1 part in the plan view of FIG. 19. A schematic cross-sectional view of an embodiment taken along the dotted line in FIG. 20 is illustrated in FIG. 21.

FIG. 21 is a schematic cross-sectional view illustrating a method of manufacturing a semiconductor layer after an excimer laser annealing process.

FIG. 21 schematically illustrates that the second part BML2 is disposed on the first part BML1 and the semiconductor layer ACT is disposed on the second part BML2. FIG. 21 schematically illustrates a shape in which steps and inclined surfaces are generated in the semiconductor layer ACT by the first part BML1 and the second part BML2. In a cross-sectional view, low-temperature polysilicon Poly-Si may be formed in the semiconductor layer ACT that overlaps a region of the first part BML1 that does not overlap the second part BML2. In other words, low-temperature polysilicon Poly-Si may be formed in the semiconductor layer ACT that overlaps the first part BML1 that is not covered by the second part BML2. In other words, low-temperature polysilicon Poly-Si may be formed on the flat surface of the semiconductor layer ACT, which is lower in height than the inclined surface on which reflected light is formed.

In an embodiment of the disclosure, the semiconductor layer ACT may partially include low-temperature polysilicon Poly-Si formed using an inclined surface. The semiconductor layer ACT may be shaped according to a design. In other words, the semiconductor layer ACT may be etched after the laser annealing process is performed, leaving only a portion of the applied semiconductor layer ACT remaining. Therefore, in an embodiment of the disclosure, a portion of the semiconductor layer ACT may be low-temperature polysilicon Poly-Si in which an excimer laser annealing process using an inclined surface was performed, and another portion of the semiconductor layer ACT may be low-temperature polysilicon Poly-Si in which an excimer laser annealing process of the comparative example was performed without using an inclined surface. According to an embodiment of the disclosure, the electron mobility of the semiconductor layer ACT may have an average greater than or equal to about 200 cm2/V·s.

FIG. 21 schematically illustrates the semiconductor layer ACT formed by irradiating the applied semiconductor layer ACT with a laser and performing an excimer laser annealing process to form low-temperature polysilicon Poly-Si, followed by an etching process.

As described above, in case that the excimer laser annealing process is performed using the inclined surface of the applied semiconductor layer ACT, the regularity of silicon particles may be improved compared to the case that the excimer laser annealing process of the comparative example is performed.

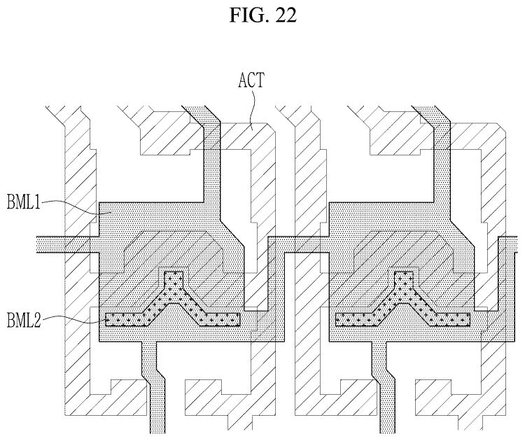

FIG. 22 is a plan view of a display device including only a semiconductor layer and a lower metal layer according to another embodiment.

FIG. 22 schematically illustrates another embodiment of the second part BML2.

Compared to the second part BML2 of FIG. 20, parts unnecessary for the excimer laser annealing process may be excluded from the second part BML2 of FIG. 22.

The second part BML2 of FIG. 22 may be similar to the second part BML2 of FIG. 20, and in a plan view, a side of the semiconductor layer ACT and a side of the second part BML2 may be parallel to each other.

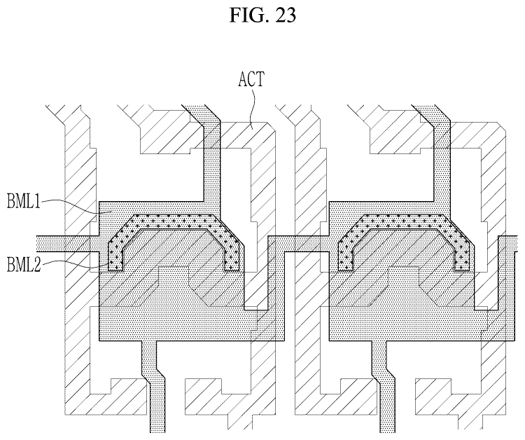

FIG. 23 is a plan view of a display device including only a semiconductor layer and a lower metal layer according to another embodiment.

FIG. 23 schematically illustrates another embodiment of the second part BML2.

The second part BML2 in FIG. 20 may be disposed on a side of the semiconductor layer ACT area where the excimer laser annealing process using an inclined surface is to be performed, whereas the second part BML2 in FIG. 23 may be placed on another side of the semiconductor layer ACT area where the excimer laser annealing process is to be performed. Although the second part BML2 in FIG. 20 and the second part BML2 in FIG. 23 are arranged at different positions, an excimer laser annealing process may be performed on the semiconductor layer ACT at a same position.

In the second part BML2 of FIG. 23, in a plan view, a side of the semiconductor layer ACT may be parallel to a side of the second part BML2.

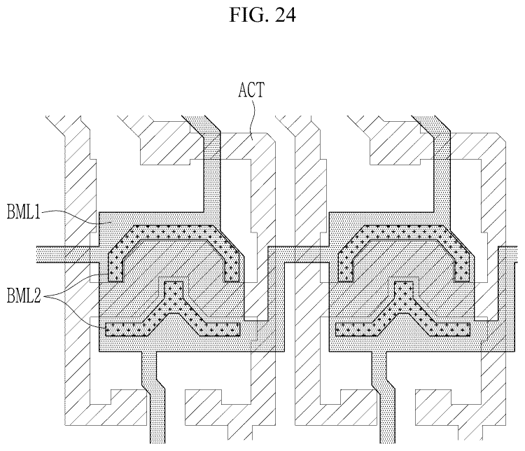

FIG. 24 is a plan view of a display device including only a semiconductor layer and a lower metal layer according to another embodiment.

FIG. 24 schematically illustrates another embodiment of the second part BML2.

For example, in a plan view, the second part BML2 may have one or more areas. In a plan view, the second part BML2 may have an additional area. The second part BML2 of FIG. 24 may include both the second part BML2 of FIG. 22 and the second part BML2 of FIG. 23. As a result, reflected light may be generated in the second part from both the side and the another side of the semiconductor layer ACT area where an excimer laser annealing process using an inclined surface is to be performed. Therefore, the excimer laser annealing process may be performed using stronger reflected light. Because of this, the regularity of the silicon particles may be further improved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device, comprising:
a first barrier layer disposed on a substrate;
a lower metal layer disposed on the first barrier layer; and
a semiconductor layer disposed on the lower metal layer, wherein
in a cross-sectional view, the lower metal layer includes a first part spaced apart from the semiconductor layer and a second part closer to the semiconductor layer,
in a plan view, an area of the second part is smaller than an area of the first part, and
a side of the semiconductor layer and a side of the second part, which is adjacent to the semiconductor layer, are parallel to each other.

2. The display device of claim 1, further comprising:
a buffer layer disposed between the semiconductor layer and the lower metal layer.

3. The display device of claim 2, further comprising:
a second barrier layer disposed between the lower metal layer and the buffer layer.

4. The display device of claim 2, wherein in a cross-sectional view, a thickness of the buffer layer is about 1 to about 4 times a thickness of the lower metal layer.

5. The display device of claim 1, wherein in a plan view, the second part has an additional area.

6. The display device of claim 1, wherein in a cross-sectional view, the first part and the second part are continuous.

7. The display device of claim 1, wherein in a cross-sectional view, the second part includes an inclined surface at an end.

8. The display device of claim 7, wherein an angle of the inclined surface is in a range of about 30 degrees to about 60 degrees.

9. The display device of claim 1, wherein in a cross-sectional view, the first part and the second part are spaced apart from each other.

10. The display device of claim 9, further comprising:
a third barrier layer disposed between the first part and the second part.

11. A method of manufacturing a display device, comprising:
forming a first barrier layer on a substrate;
forming a lower metal layer on the first barrier layer; and
forming a semiconductor layer on the lower metal layer,
wherein the forming of the semiconductor layer on the lower metal layer includes applying the semiconductor layer on the lower metal layer, and irradiating a laser simultaneously to a flat surface and an inclined surface of the semiconductor layer.

12. The method of manufacturing the display device of claim 11, wherein an incident angle of the laser is in a range of about 0 degrees to about 80 degrees.

13. The method of manufacturing the display device of claim 11, wherein the inclined surface has a height higher than the flat surface.

14. The method of manufacturing the display device of claim 11, wherein
in a cross-sectional view, the lower metal layer includes a first part spaced apart from the semiconductor layer and a second part closer to the semiconductor layer, and
in a plan view, an area of the second part is smaller than an area of the first part.

15. The method of manufacturing the display device of claim 14, wherein a side of the semiconductor layer and a side of the second part, which is adjacent to the semiconductor layer, are parallel to each other.

16. The method of manufacturing the display device of claim 11, wherein the forming of the lower metal layer includes forming a step in the lower metal layer using a photoresist.

17. The method of manufacturing the display device of claim 16, wherein the photoresist includes a step.

18. The method of manufacturing the display device of claim 11, further comprising:
forming a buffer layer between the semiconductor layer and the lower metal layer.

19. The method of manufacturing the display device of claim 18, further comprising:
forming a second barrier layer between the lower metal layer and the buffer layer.

20. The method of manufacturing the display device of claim 18, wherein in a cross-sectional view, a thickness of the buffer layer is about 1 to about 4 times a thickness of the lower metal layer.
